(19) United States
(12) Patent Application Publication
(10) Pub. No.: US 2012/0000425 A1
(43) Pub. Date: Jan. 5, 2012

(54) Apparatus for Processing Substrate

(75) Inventors: Byoung-Keon Park, Yongin-City (KR); Ki-Yong Lee, Yongin-City (KR); Jin-Wook Seo, Yongin-City (KR); Min-Jae Jeong, Yongin-City (KR); Jong-Won Hong, Yongin-City (KR); Heung-Yeol Na, Yongin-City (KR); Tae-Hoon Yang, Yongin-City (KR); Yun-Mo Chung, Yongin-City (KR); Eu-Gene Kang, Yongin-City (KR); Seok-Rak Chang, Yongin-City (KR); Dong-Hyun Lee, Yongin-City (KR); Kil-Won Lee, Yongin-City (KR); Jong-Ryuk Park, Yongin-City (KR); Bo-Kyung Choi, Yongin-City (KR); Won-Bong Baek, Yongin-City (KR); Ivan Maidanchuk, Yongin-City (KR); Byung-Soo So, Yongin-City (KR); Jae-Wan Jung, Yongin-City (KR)

(73) Assignee: Samsung Mobile Display Co., Ltd., Yongin-city (KR)

(21) Appl. No.: 12/985,649

(22) Filed: Jan. 6, 2011

(30) Foreign Application Priority Data
Jun. 30, 2010 (KR) 10-2010-0062876

(51) Int. Cl. C23C 16/458; C23C 16/455

(52) U.S. Cl. 118/724

(57) ABSTRACT

A substrate processing apparatus that simultaneously forms thin films on a plurality of substrates and performs heat treatment includes: a plurality of substrate holders, each including a substrate support that supports a substrate and a first gas pipe having one or a plurality of injection holes; a boat where the plurality of substrate holders are stacked and including a second gas pipe connected with the first gas pipe of each of the substrate holders; a process chamber providing a space in which the substrates stacked in the boat are processed; a conveying unit that carries the boat into/out of the process chamber; a first heating unit disposed outside the process chamber; and a gas supply unit including a third gas pipe connected with the second gas pipe and supplying a heated or cooled gas into the second gas pipe.

### CROSS-REFERENCE TO RELATED APPLICATION

This application claims the benefit of Korean Application No. 10-2010-0062876, filed Jun. 30, 2010, in the Korean Intellectual Property Office, the disclosure of which is incorporated herein by reference.

### BACKGROUND

1. Field

The described technology relates generally to a substrate processing apparatus that simultaneously forms thin films or applies heat treatment to a plurality of substrates, and more particularly, to a substrate processing apparatus that can uniformly process a plurality of substrates by uniformly heating the substrates stacked on a boat disposed in a processing chamber.

2. Description of the Related Art

Flat panel displays have replaced cathode ray tube displays, due to superior characteristics, including light weight and small size. Typical examples of flat panel displays are liquid crystal displays (LCD) and organic light emitting diode (OLED) displays. Organic light emitting diode displays have excellent luminescence characteristics and viewing angle characteristics, as compared with liquid crystal displays (LCD) and do not need a backlight, such that they can be implemented in very small sizes.

The organic light emitting diode display generates light having a specific wavelength by energy from excitons produced by recombination of electrons injected from the cathode to an organic thin film and holes injected from the anode. Organic light emitting displays are classified into a passive matrix type and an active matrix type in accordance with the operation method, in which the active matrix type includes a circuit using a thin film transistor (TFT).

The flat panel displays are manufactured by forming a thin film with a predetermined pattern, which has electrical properties, from an organic substance or an inorganic substance on a substrate or performing heat treatment on the formed thin film. Methods of forming the thin film include physical vapor deposition (PVD), in which sputtering os used to apply and deposit plasma on a target and chemical vapor deposition (CVD), in which a reaction gas containing a source material is ejected onto a substrate, chemically forming a film on the substrate. Further, the chemical vapor deposition method is divided by the deposition type into low pressure chemical vapor deposition (LPCVD), plasma chemical vapor deposition (PECVD), and atomic layer deposition (ALD), which forms a source material in an atomic layer unit. The atomic layer deposition (ALD) method provides good uniformity of a thin film and step coverage, as compared with the physical vapor deposition method, such that it is increasingly used in the semiconductor process.

The chemical vapor deposition method uses batch type equipment that puts a plurality of substrates into a deposition chamber at one time and simultaneously forms thin films on the substrates, because the forming speed of a thin film is low when plasma is not used.

In general, substrate processing apparatuses that simultaneously form thin films on a plurality of substrates and perform heat treatment using the lower pressure chemical vapor deposition or the atomic layer deposition include a process chamber providing a space for processing, a boat including a plurality of stacked substrates, a heating unit disposed outside the process chamber, and a conveying unit that carries the boat into/out of the process chamber. In this configuration, the substrate processing apparatuses may further include substrate holders that are seated on the substrates and stacked in the boat, in order to prevent the substrates stacked in the boat from sagging.

In the substrate processing apparatuses, since the inside of the process chamber is heated by the heating unit at the outside of the process chamber and since a large process chamber is needed to accommodate the boat with stacked substrates, it is difficult to uniformly heat the inside of the process chamber only with the heating unit at the outside of the process chamber. Therefore, the portions stacked in the boat, particularly, the center portion and the edges are heated at different temperatures in the substrate, the time for performing heat treatment to the substrates increases, non-uniformity occurs in the formed film due to the non-uniform temperature distribution and non-uniformity occurs in the device characteristics due to differences in the heat treatment temperature. If temperature non-uniformity is excessive, substrate warpage may occur, such that following processes are impossible.

The above information disclosed in this Background section is only for enhancement of understanding of the background of the described technology and therefore it may contain information that does not form the prior art that is already known in this country to a person of ordinary skill in the art.

### SUMMARY

The described technology has been made in an effort to provide a substrate processing apparatus having advantages of uniformly processing a plurality of substrates in a boat by uniformly heating the substrates stacked in the boat.

An exemplary embodiment provides a substrate processing apparatus that includes: a plurality of substrate holders, each including a substrate support that supports a substrate and a first gas pipe having one or more injection holes; a boat where the plurality of substrate holders are stacked and including a second gas pipe connected with each of the first gas pipes; a process chamber providing a space in which the substrates stacked in the boat are processed; a conveying unit that carries the boat into/out of the process chamber; a first heating unit disposed outside the process chamber; and a gas supply unit including a third gas pipe connected with the second gas pipe and supplying a heated or cooled gas into the second gas pipe.

According to the exemplary embodiment, the substrate processing apparatus can uniformly process a plurality of substrates while uniformly heating the substrates and maintaining a predetermined temperature, by providing gas pipes through which a cooled or heated gas can flow in a boat and substrate holders where substrates are seated. The gas pipes include one or more injection holes to inject the gas in the gas pipes formed in the substrate holders such that a heated or cooled gas is injected onto the surface of the substrates.

According to a non-limiting aspect, there is provided a substrate processing apparatus, comprising a process chamber; a boat that supports a plurality of substrate holders in the process chamber, wherein each substrate holder includes a surface that supports a substrate and wherein each substrate holder includes a first gas pipe disposed at a surface of the substrate holder opposite to the surface supporting the substrate and having one or more injection holes; and a gas supply unit that supplies heated or cooled gas to the one or more injection holes of the first gas pipe.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic view showing a substrate processing apparatus according to an exemplary embodiment;

FIG. 2A and 2B are enlarged views of region A of FIG. 1;

FIG. 3 is a schematic view showing a substrate processing apparatus according to another exemplary embodiment;

FIG. 4A is an enlarged view of region B of FIG. 3; and

FIG. 4B is a rear view showing a substrate holder of the substrate processing apparatus according to the exemplary embodiment of FIG. 3.

### DETAILED DESCRIPTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

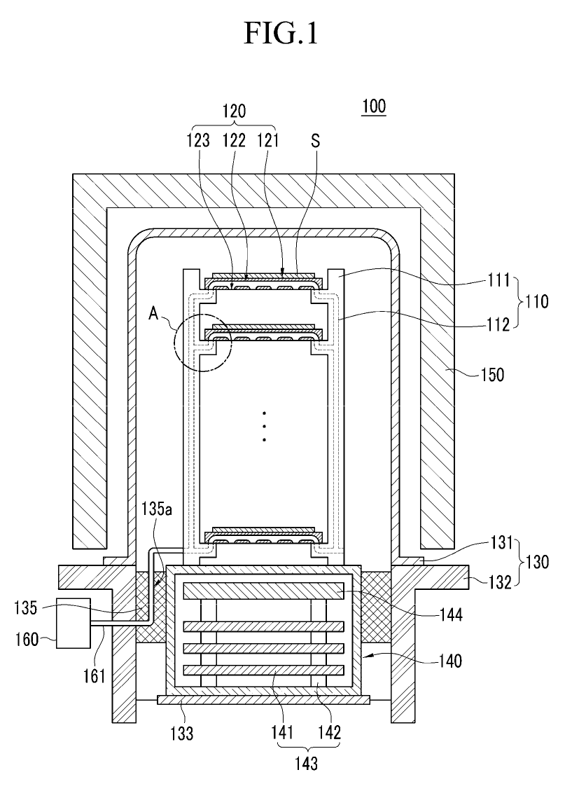

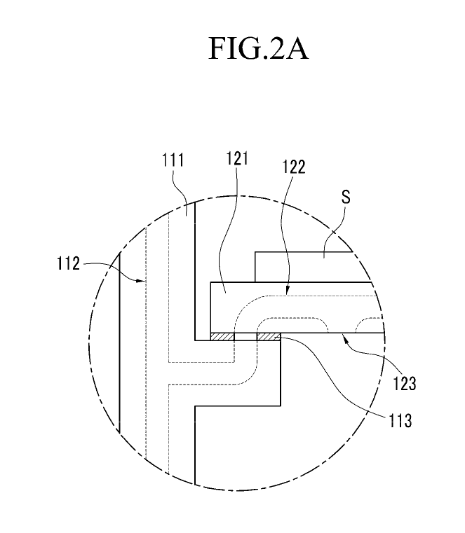

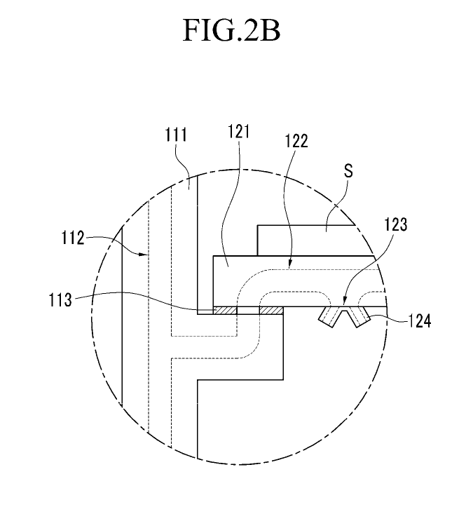

FIG. 1 is a schematic view showing a substrate processing apparatus according to an exemplary embodiment and FIG. 2A is a view enlarging the region A of FIG. 1.

Referring to FIGS. 1 and 2A, a substrate processing apparatus for processing a substrate 100 according to the first exemplary embodiment includes: a plurality of substrate holders 120 each supporting a substrate (S) and including a first gas pipe 122 having one or more first injection holes 123; a boat 110 on which the plurality of substrate holders 120 are stacked and including a second gas pipe 112 connected with each of the first gas pipes 122; a process chamber 130 providing a space for processing the substrates (S) stacked on the boat 110; a conveying unit 140 that carries the boat 110 into/out of the process chamber 130; a first heating unit 150 disposed outside the process chamber 130; and a gas supply unit 160 including a third gas pipe 161 connected with the second gas pipe 112 and supplying a heated or cooled gas into the first gas pipes 122.

The boat 110 includes the stacked substrate holders 120, each having a substrate (S) stacked thereon, such that the substrates (S) seated in the substrate holders 120 may be carried to be simultaneously processed in the process chamber 130. The boat 110 includes a boat body 111 combined with the substrate holders 120 and the second gas pipe 112 disposed inside the boat body 111 and connecting the first gas pipe 122 of each of the substrate holders 120 with the third gas pipe 161 of the gas supply unit 160.

In this configuration, a connecting member 113 may be disposed between each first gas pipe 122 and the second gas pipe 112 to prevent the heated or cooled gas supplied from the gas supply unit 160 from leaking between the first gas pipes 122 and the second gas pipe 112.

Further, although the first exemplary embodiment exemplifies when the substrate holders 120 are vertically stacked in the boat 110, alternatively, the substrate holders 120 may be horizontally arranged in the boat 110.

The substrate holders 120 are provided to prevent deformation of the substrate (S) in the processing process and damage to the substrates (S) while the boat 110 is carried by the conveying unit 140. Each of the substrate holders 120 has a substrate support 121 supporting the substrate (S) and the first gas pipe 122 positioned inside the substrate support 121 and having one or more injection holes 123.

In this configuration, the one or more injection holes 123 inject the heated or cooled gas supplied from the gas supply unit 160 under the substrate support 121 where the substrate (S) is seated in order to inject the gas onto the surface of the substrates (S) seated in the substrate holder 120 stacked under the corresponding substrate holder 120. As shown in FIG. 2B, the injection hole 123 may have nozzles 124 injecting the gas at a predetermined angle with respect to the surface of the substrate support 121.

The process chamber 130 is provided to simultaneously process the substrates (S) stacked in the boat 110, and includes a first tube 131 that prevents contact between the substrates (S) and external air in the processing process and a manifold 132 disposed under the first tube 131 and providing a space into which and out of which the boat 110 is carried. In this configuration, the process chamber 130 may further include a shutter 133 disposed at the lower portion of the manifold 132 and movable horizontally to close the process chamber 130 after the boat 110 is carried inside the process chamber 130.

The conveying unit 140 is provided to carry the boat 110 into/out of the process chamber 130 through the lower portion of the manifold 132, and may include an insulating unit 143 composed of one or more insulating plates 141 and insulating holders 142 supporting the insulating plates 141 in order to reduce loss of heat inside the process chamber 130 heated by the first heating unit 150, and may further include a second heating unit 144 disposed between the boat 110 and the insulating unit 143 to more uniformly heat the inside of the process chamber 130.

Further, the substrate processing apparatus according to this exemplary embodiment may further include a second tube 135 disposed between the conveying unit 140 and the first tube 131 of the process chamber 130 in order to minimize loss of heat in the process chamber 130. The second tube 135 may have a first hole 135a through which the third pipe 161 passes to prevent external air from flowing into the first tube 131 through the third gas pipe 161.

The first heating unit 150 is provided to heat the inside of the process chamber 130 while the substrates (S) are being processed. The first heating unit 150 is located at the outside of the process chamber 130 and may have a furnace shape surrounding the top and sides of the process chamber 130, or may be configured such that the portion of the heating unit 150 at the sides of the process chamber 130 and the portion above the top of the process chamber 130 are divided and independently operated.

The gas supply unit 160 supplies a heated gas through the third gas pipe 161 to uniformly heat the substrates (S) in the process chamber 130, or may supply a cooled gas through the third gas pipe 161 to maintain the temperature of the substrates (S) at a predetermined temperature when the inside of the process chamber 130 is overheated by the first heating unit 150.

In this configuration, a second connecting member (not shown) may be further disposed between the second gas pipe 112 and the third gas pipe 161 to prevent the heated or cooled gas supplied from the gas supply unit 160 from leaking between the third gas pipe 161 and the second gas pipe 112.

As a result, the substrate processing apparatus of the exemplary embodiment described above uniformly heats a plurality of substrates stacked in the boat disposed in the process chamber, by providing a first gas pipe in each of the substrate holders supporting a substrate, providing the second gas pipe connecting each first gas pipe with the third gas pipe of the gas supply unit inside the boat having the substrate holders, and providing the each first gas pipe with one or more injection holes such that a heated or cooled gas supplied from the gas supply unit is injected onto the surface of the stacked substrates.

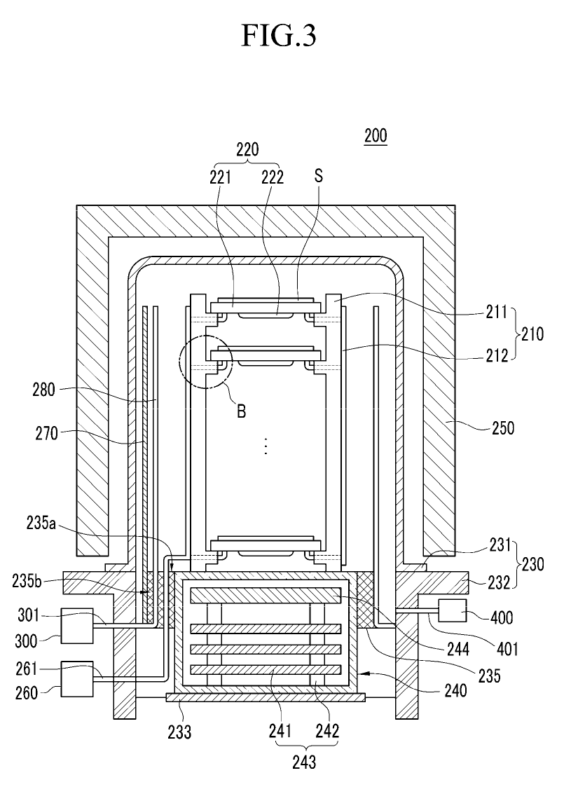

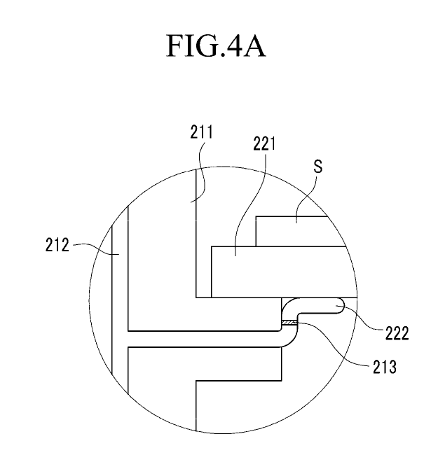

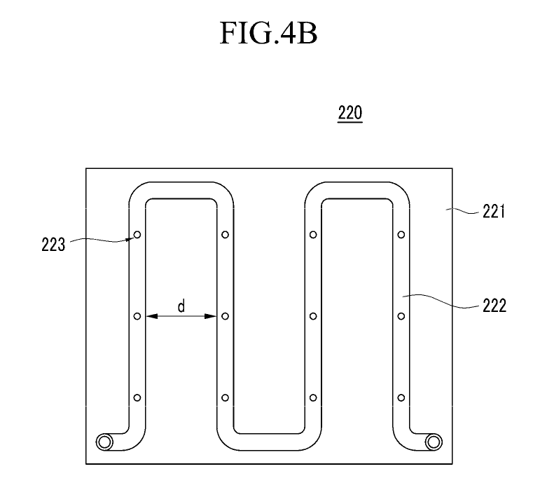

FIG. 3 is a schematic view showing a substrate processing apparatus according to another exemplary embodiment, FIG. 4A is an enlarged view of the region B of FIG. 3, and FIG. 4B is a rear view showing a substrate holder of the substrate processing apparatus according to the exemplary embodiment of FIG. 3.

Referring to FIGS. 3, 4A, and 4B, a substrate processing apparatus for processing a substrate 200 according to this exemplary embodiment includes: a process chamber 230; substrate holders 220 each including a substrate support 221 supporting a substrate (S) and a first gas pipe 222 having one or two injection holes 223, in close contact with the bottom of the substrate support 221; a boat 210 including a boat body 211 in which the substrate holders 220 are stacked and a second gas pipe 212 in close contact to the boat body 211; a first heating unit 250 disposed outside the process chamber 230; a conveying unit 240 that carries the boat 210 into/out of the process chamber 230; and a gas supply unit 260 including a third gas pipe 261 connected with the second gas pipe 212 and supplying heated or cooled gas into each of the the first gas pipes 222.

The boat 210 makes it possible to simultaneously process the substrates (S) seated in the substrate holders 220 in the process chamber 230. The boat 210 includes the boat body 211 combined with the substrate holders 220 and the second gas pipe 212 connecting the first gas pipes 222 of the substrate holders 220 with the third gas pipe 261 of the gas supply unit 260, while being in close contact with the boat body 211.

In this configuration, with respect to each substrate holder 220, a connecting member 213 may be disposed between the first gas pipe 222 of the substrate holder 220 and the second gas pipe 212 to prevent the heated or cooled gas supplied from the gas supply unit 260 from leaking between the first gas pipe 222 and the second gas pipe 212.

The substrate holders 220 are provided to prevent deformation of the substrate (S) in the processing process and damage to the substrates (S) while the boat 210 is carried by the conveying unit 240. Each substrate holder 220 includes a substrate support 221 that supports the substrate (S) and the first gas pipe 222 positioned under the bottom of the substrate support 221 and having one or more injection holes 223.

As shown in FIG. 4B, each first gas pipe 222 may have a serpentine configuration in which the first gas pipe forms parallel portions across the bottom face of the substrate support 221. In this configuration, it is desirable that the distance ‘d’ between the parallel portions of the gas pipes 222 is equal to or greater than the width of a robot arm (not shown) that stacks the substrate holders 220 in the boat 210, in order to prevent the first gas pipes 222 from being damaged by the robot arm.

Further, one or more of the injection holes 223 inject the heated or cooled gas supplied from the gas supply unit 260 onto the surface of the substrates (S) seated in the substrate holder 220 stacked under the corresponding substrate holder 220. As in the exemplary embodiment of FIG. 1, the injection hole 223 may have nozzles (not shown) injecting the gas at a predetermined angle with respect to the surface of the substrate support 221.

The process chamber 230 is provided to simultaneously process the substrates (S) stacked in the boat 210, and includes a first tube 231 preventing contact between the substrates (S) and external air in the processing process and a manifold 232 disposed under the first tube 231. In this configuration, the process chamber 230 may further include a shutter 233 disposed at the lower portion of manifold 232 and movable horizontally to close the process chamber 230 after the boat 210 is carried inside the process chamber 230.

Further, the process chamber 230 may further include a second tube 235 disposed between the conveying unit 240 and the first tube 231 of the process chamber 230 in order to minimize loss of heat in the process chamber 230. The second tube 235 may have a first hole 235a through which the third pipe 261 passes to prevent external air from flowing into the first tube 231 through the third gas pipe 261.

The substrate processing apparatus according to the exemplary embodiment of FIG. 3 forms uniform thin films on the substrates (S) by including an inflow pipe 301 through which a reaction gas flows inside from a reaction gas supply unit 300 and an exhaust pipe 401 connected to an exhaust pump 400 to discharge the reaction gas, which does not react with the substrate (S), which are disposed in the second manifold 232, and further including a gas injecting unit 280 connected with the inflow pipe 301 and injecting the reaction gas onto the substrates (S) stacked in the second boat 210.

In this configuration, The second tube 235 may have a second hole 235b through which the gas injecting unit 280 connected with the inflow pipe 301 passes to prevent external air from flowing inside the first tube 231 through the space between the conveying unit 240 and the manifold 232. As a non-limiting example, the gas injecting unit 280 may extend to the end of the boat 210 in the direction of stacking the substrates (S) in the boat 210 to uniformly inject the reaction gas onto the substrates (S) stacked inside the boat 210.

Further, the substrate processing apparatus according to the exemplary embodiment of FIG. 3 may further include a third tube 270 disposed between the conveying unit 240 and the manifold 232 in order to minimize loss of heat from the process chamber 220. The second tube 235 may have a length as great as the overlap area of the conveying unit 240 and the third tube 270 to more reduce loss of heat from the process chamber 220.

The conveying unit 240 is provided to carry the boat 210 into/out of the process chamber 230 through the lower portion of the manifold 232, and may include an insulating unit 243 composed of one or more insulating plates 241 and insulating holders 242 supporting the insulating plates 241 in order to reduce loss of heat inside the process chamber 230 heated by the first heating unit 250. The conveying unit 240 may further include a second heating unit 244 disposed between the boat 210 and the insulating unit 243 to more uniformly heat the inside of the process chamber 230.

The first heating unit 250 is provided at the outside of the second process chamber 230 to heat the inside of the process chamber 230 during processing of the substrates (S). The first heating unit 250 may have a furnace shape surrounding the top and sides of the process chamber 230, or may be configured such that a portion of the first heating unit 250 at the sides of the process chamber 230 and a portion above the top of the process chamber 230 are divided and independently operated.

The gas supply 260 supplies a heated gas through the third gas pipe 261 to uniformly heat the substrates (S) in the process chamber 230, or may supply a cooled gas through the third gas pipe 261 to maintain temperature of the substrates (S) at a predetermined temperature, when the inside of the process chamber 230 is overheated by the first heating unit 250.

In this configuration, a fourth connecting member (not shown) may be further disposed between the second gas pipe 212 and the third gas pipe 261 to prevent the heated or cooled gas supplied from the gas supply 260 from leaking between the third gas pipe 261 and the second gas pipe 212.

As a result, the substrate processing apparatus according to the exemplary embodiment described above uniformly heats a plurality of substrates stacked in the boat by injecting a heated or cooled gas supplied from the gas supply unit onto the surface of the stacked substrates while preventing a decrease of strength of the boat body and the substrate supports, as compared with the exemplary embodiment of FIG. 1, by disposing the bottom of the first gas pipe having one or more injection holes under the substrate support of the substrate holder, disposing the second gas pipe connecting the first gas pipe with the third gas pipe of the gas supply unit, in close contact with the boat body where the substrate holders are stacked.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A substrate processing apparatus, comprising:
a plurality of substrate holders, each including a substrate support that supports a substrate and a first gas pipe having one or more injection holes;
a boat where the plurality of substrate holders are stacked and including a second gas pipe connected with the first gas pipe of each of the substrate holders;
a process chamber providing a space in which the substrates stacked in the boat are processed;
a conveying unit that carries the boat into/out of the process chamber;
a first heating unit disposed outside the process chamber; and
a gas supply unit including a third gas pipe connected with the second gas pipe and supplying a heated or cooled gas into the second gas pipe.

2. The apparatus of claim 1, wherein:
each of the first gas pipes is disposed in one of the substrate supports.

3. The apparatus of claim 1, wherein:
the second gas pipe is disposed in the boat.

4. The apparatus of claim 1, further comprising:
first connecting members disposed between each of the first gas pipes and the second gas pipe.

5. The apparatus of claim 1, further comprising:
a second connecting member disposed between the second gas pipe and the third gas pipe.

6. The apparatus of claim 1, wherein:
each of the first gas pipes further includes nozzles positioned at the one or more injection holes and having a predetermined angle with respect to the surface of the substrate support.

7. The apparatus of claim 6, wherein:
the nozzles inject a gas supplied through a respective first gas pipe in a plurality of directions.

8. The apparatus of claim 1, wherein:
each of the first gas pipes has a serpentine configuration in which the first gas pipe forms parallel portions across the bottom face of the respective substrate support and wherein a distance between parallel portions of the gas pipe is equal to or greater than the width of a robot arm that seats the substrate holders in the boat.

9. The apparatus of claim 1, wherein:
the conveying unit includes an insulating unit.

10. The apparatus of claim 9, wherein:
the insulating unit includes one or more insulating plates and insulating holders supporting the insulating plates.

11. The apparatus of claim 9, wherein:
the conveying unit further includes a second heating unit disposed between the insulating unit and the boat.

12. The apparatus of claim 1, wherein:
the process chamber includes a first tube that prevents external air from flowing to the substrates and a manifold enclosed the first tube and providing a space into which and out of which the boat is carried.

13. The apparatus of claim 12, further comprising:
a second tube having a first hole through which the third gas pipe passes and disposed between the manifold and the conveying unit.

14. The apparatus of claim 12, further comprising:
a gas injecting unit passing through the manifold and connected with a fourth pipe supplying a reaction gas, wherein the gas injecting unit injects the reaction gas onto the substrates.

15. The apparatus of claim 12, further comprising:
an exhaust pump connected with an exhaust pipe passing through the manifold, wherein the exhaust pump maintains the inside of the process chamber in a vacuum.

16. The apparatus of claim 12, further comprising:
a second tube disposed between the first tube and the boat.

17. The apparatus of claim 1, further comprising:
a shutter disposed under the process chamber to close the process chamber.

18. A substrate processing apparatus, comprising:
a process chamber;
a boat that supports a plurality of substrate holders in the process chamber, wherein each substrate holder includes a surface that supports a substrate and wherein each substrate holder includes a first gas pipe disposed at a surface of the substrate holder opposite to the surface supporting the substrate and having one or more injection holes; and
a gas supply unit that supplies heated or cooled gas to the one or more injection holes of the first gas pipe of each of the substrate holders.

19. The apparatus of claim 18, further comprising a second gas pipe disposed in the boat and a third gas pipe extending from the gas supply unit, wherein the first gas pipe of each of the substrate holders, the second gas pipe and the third gas pipe are joined together to provide a conduit between the gas supply unit and the injection holes of the first gas pipe of each of the substrate holders.

20. The apparatus of claim 19, further comprising a first connecting member disposed between the first gas pipe of each of the substrate holders and the second gas pipe and a second connecting member disposed between the second gas pipe and the third gas pipe.
